(19) United States
(12) Patent Application Publication
(10) Pub. No.: US 2026/0271742 A1
(43) Pub. Date: Sep. 10, 2026

(54) SEMICONDUCTOR DEVICE

(71) Applicant: ROHM Co., LTD., Kyoto (JP)

(72) Inventor: Naoyuki Sano, Kyolo (JP)

(21) Appl. No.: 19/556,357

(22) Filed: Mar. 4, 2026

(30) Foreign Application Priority Data
Mar. 6, 2025 (JP) 2025-035538

(51) Int. Cl. H10W 70/40; H10W 90/00

(52) U.S. Cl. CPC H10W 70/415; H10W 70/424; H10W 90/726

(57) ABSTRACT

Provided is a semiconductor device including a semiconductor element having a main body that includes a first surface and a second surface facing away from each other in a first direction, and a first terminal, a second terminal, a third terminal, and a fourth terminal each facing the second surface. The semiconductor element has a first electrode, a second electrode, a third electrode, and a fourth electrode positioned closer to the second surface than the first surface. The first terminal, the second terminal, the third terminal, and the fourth terminal have a first junction region, a second junction region, a third junction region, and a fourth junction region, respectively.

### PRIORITY

The present disclosure contains subject matter related to that disclosed in Japanese Priority Patent Application JP 2025-035538 filed in the Japan Patent Office on Mar. 6, 2025, the entire content of which is hereby incorporated by reference.

### BACKGROUND

The present disclosure relates to a semiconductor device.

PCT Patent Publication No. WO2021/177034, referred to as Patent Document 1 hereinafter, discloses an exemplary semiconductor device that has a conductive member and a semiconductor element conductively bonded to one side of the conductive member in its thickness direction. The semiconductor element has multiple electrodes. Each of the electrodes is conductively bonded to the conductive member. The semiconductor element is thus flip-chip bonded to the conductor member.

Besides the configuration of the semiconductor device disclosed by Patent Document 1, there is present another configuration in which the multiple electrodes of the semiconductor element are arranged to be line symmetric relative to an axis passing through the center of the semiconductor element and point symmetric relative to the center of the semiconductor element. In the manufacture of the semiconductor device of this configuration, the semiconductor element might be erroneously mounted on the conductive member. This mounting error is difficult to detect if separate steps using inspection equipment are not carried out.

### BRIEF DESCRIPTION OF THE DRAWINGS

FIG. 1 is a plan view of a semiconductor device as a first embodiment of the present disclosure, the semiconductor device being seen through a sealing resin;

FIG. 2 is another plan view corresponding to FIG. 1, the semiconductor device being seen further through a semiconductor element;

FIG. 3 is a bottom view of the semiconductor device in FIG. 1;

FIG. 4 is a front view of the semiconductor device in FIG. 1;

FIG. 5 is a right view of the semiconductor device in FIG. 1;

FIG. 6 is a sectional view taken on line VI-VI in FIG. 1;

FIG. 7 is a sectional view taken on line VII-VII in FIG. 1;

FIG. 8 is a sectional view taken on line VIII-VIII line in FIG. 1;

FIG. 9 is a sectional view taken on line IX-IX line in FIG. 1;

FIG. 10 is a plan view of the semiconductor device in FIG. 1 rotated 180 degrees in planar view, the semiconductor device being seen through the main body of the semiconductor element and the sealing resin;

FIG. 11 is a plan view of the semiconductor device in FIG. 1 rotated 90 degrees clockwise in planar view, the semiconductor device being seen through the main body of the semiconductor element and the sealing resin;

FIG. 12 is a plan view of the semiconductor device in FIG. 1 rotated 90 degrees counterclockwise in planar view, the semiconductor device being seen through the main body of the semiconductor element and the sealing resin;

FIG. 13 is a partially enlarged view of FIG. 10;

FIG. 14 is a partially enlarged plan view of a semiconductor device as a second embodiment of the present disclosure, the drawing corresponding to FIG. 13;

FIG. 15 is a partially enlarged plan view of a semiconductor device as a third embodiment of the present disclosure, the drawing corresponding to FIG. 13;

FIG. 16 is a partially enlarged plan view of a semiconductor device as a fourth embodiment of the present disclosure, the drawing corresponding to FIG. 13;

FIG. 17 is a plan view of a semiconductor device as a fifth embodiment of the present disclosure, the semiconductor device being seen through a sealing resin;

FIG. 18 is a sectional view taken on line XVIII-XVIII line in FIG. 17;

FIG. 19 is a sectional view taken on line XIX-XIX line in FIG. 17;

FIG. 20 is a plan view of a semiconductor device as a sixth embodiment of the present disclosure, the semiconductor device being seen through a sealing resin;

FIG. 21 is a plan view corresponding to FIG. 20, the semiconductor device being seen further through a semiconductor element;

FIG. 22 is a sectional view taken on line XXII-XXII line in FIG. 20;

FIG. 23 is a sectional view taken on line XXIII-XXIII line in FIG. 20;

FIG. 24 is a plan view of a semiconductor device as a seventh embodiment of the present disclosure, the semiconductor device being seen through a sealing resin; and

FIG. 25 is a sectional view taken on line XXV-XXV line in FIG. 24.

### DETAILED DESCRIPTION

The present disclosure will be described in detail with reference to the attached drawings.

### First Embodiment

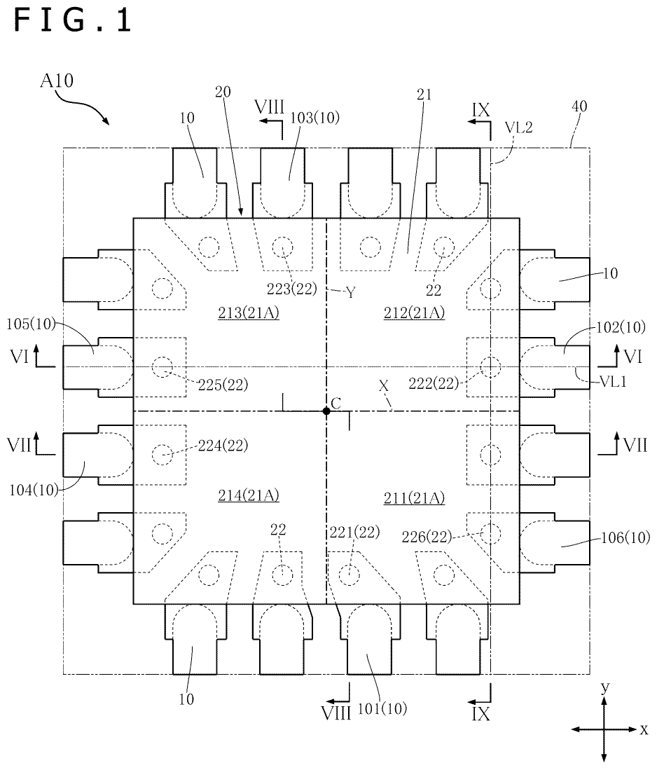

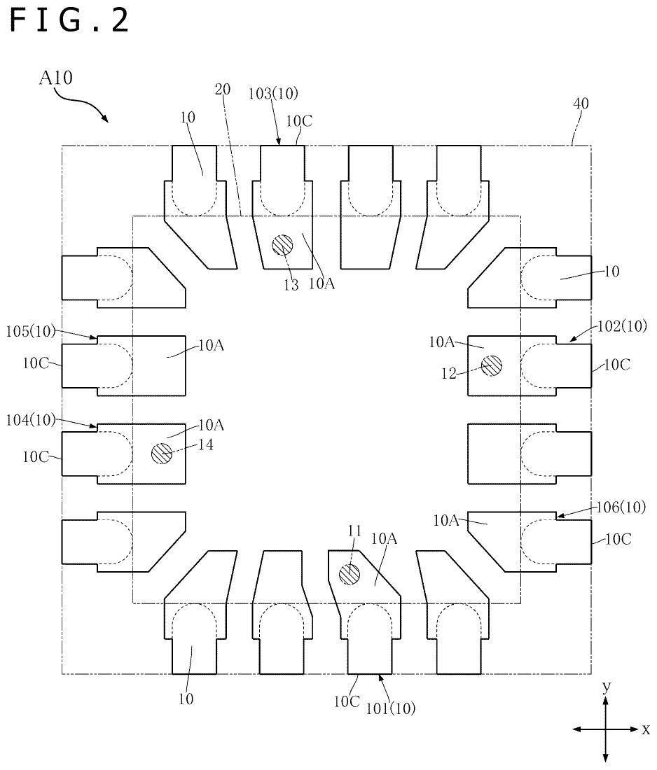

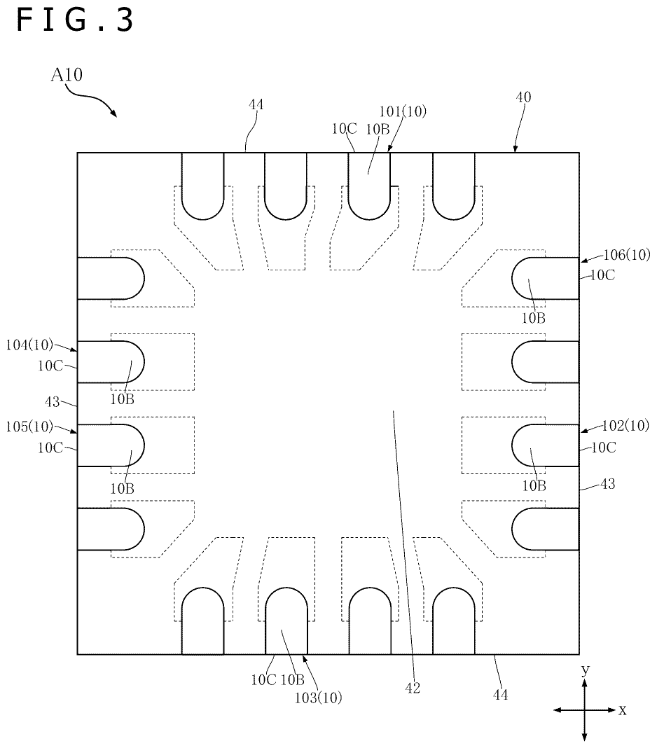

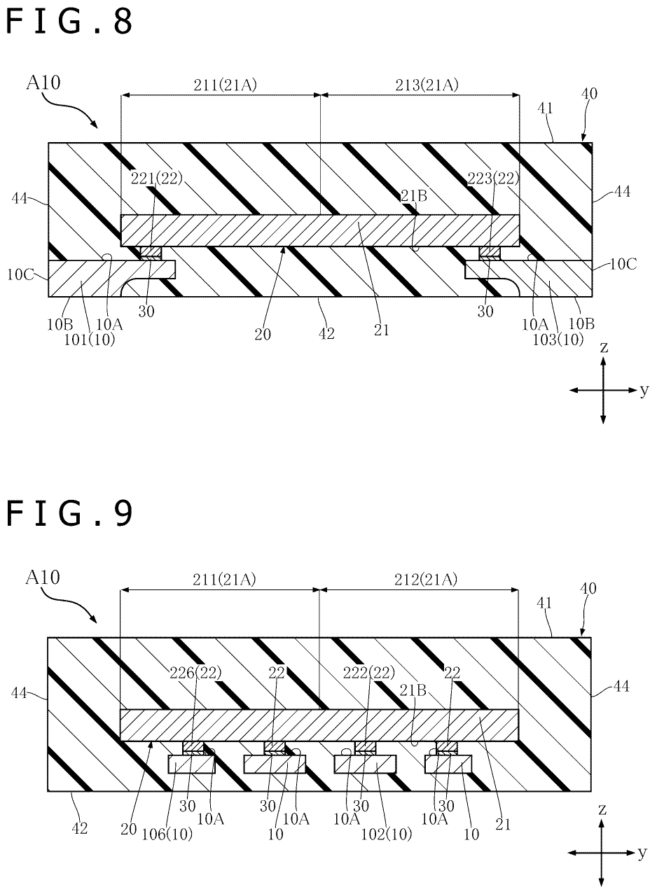

A semiconductor device A10 as a first embodiment of the present disclosure will now be described below with reference to FIGS. 1 through 13. First, the configuration of the semiconductor device A10 is explained by referencing FIGS. 1 through 9. The semiconductor device A10 has multiple terminals 10, a semiconductor element 20, and a sealing resin 40. The semiconductor device A10, which is in a resin package format here, is surface-mounted on a wiring board. This resin package format is a quad flat non-leaded package (QFN) of which the multiple lead wires do not protrude from the sealing resin 40. For ease of understanding, FIG. 1 depicts the semiconductor device A10 seen through the sealing resin 40. To also aid understanding, FIG. 2 depicts the semiconductor device A10 seen further through the semiconductor element 20 with respect to FIG. 1. In FIG. 1, the transparent sealing resin 40 is indicated by imaginary lines (two-dot-dash lines). In FIG. 2, the transparent semiconductor element 20 and sealing resin 40 are indicated by imaginary lines.

In describing the semiconductor device A10, a normal direction of each of the multiple terminals 10, to be discussed later, with respect to the element-mounting surface 10A is referred to as the first direction z. A direction perpendicular to the first direction z is referred to as the second direction x. A direction perpendicular to the first direction z and to the second direction x is referred to as the third direction y. As depicted in FIG. 1, the semiconductor device A10 is rectangular in shape when viewed in the first direction z.

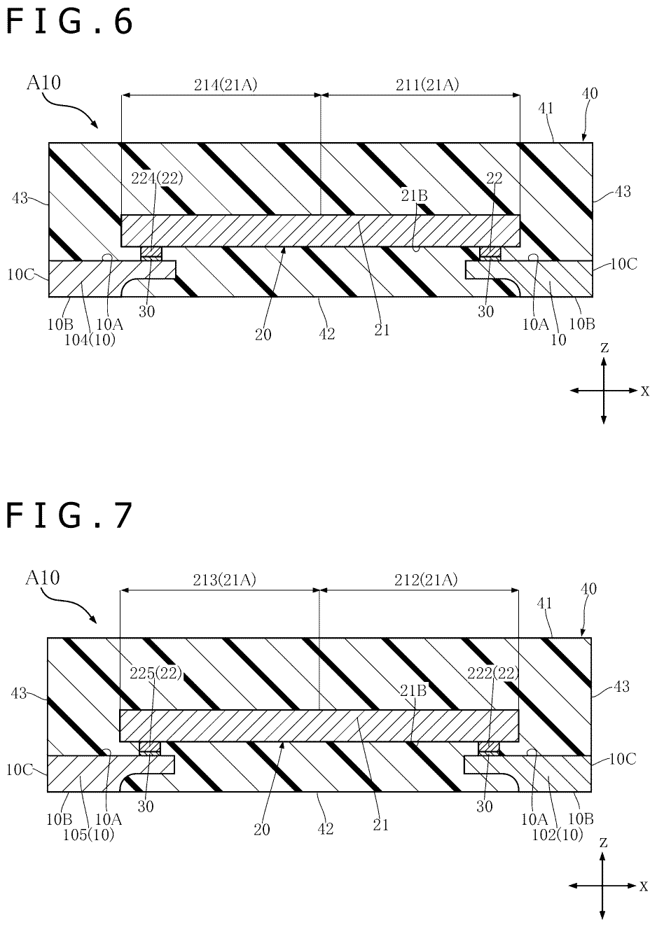

The sealing resin 40 covers portions of the multiple terminals 10 and the semiconductor element 20 as depicted in FIGS. 6 through 9. The sealing resin 40 has an electrical insulation property. A typical material of the sealing resin 40 is a black epoxy resin.

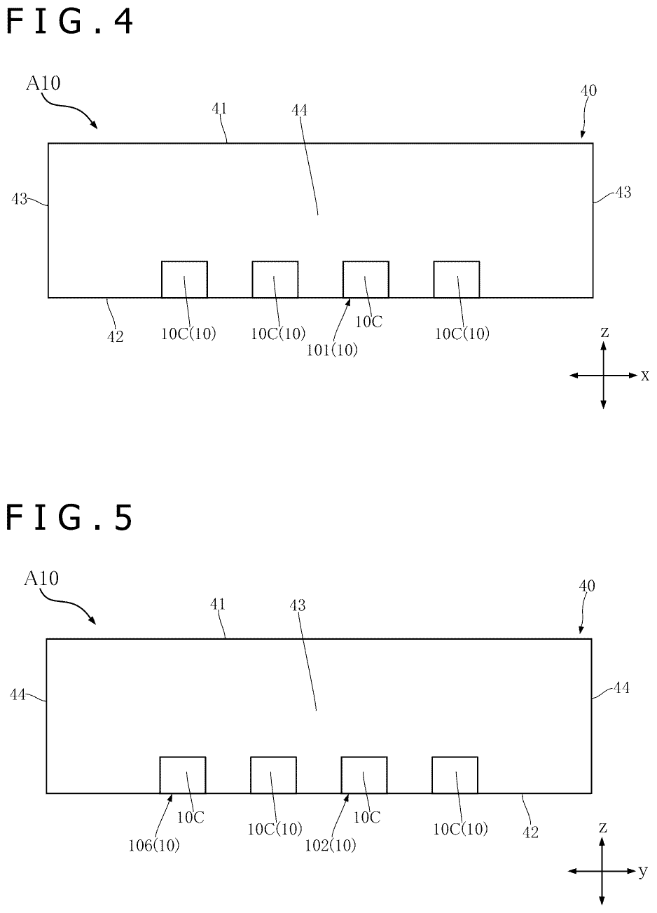

As depicted in FIGS. 4 through 9, the sealing resin 40 has a top surface 41, a base end surface 42, two first side surfaces 43, and two second side surfaces 44. The top surface 41 and the base end surface 42 face away from each other in the first direction z. Of these surfaces, the top surface 41 faces in an opposite direction where the multiple terminals 10 are positioned in reference to the semiconductor element 20 in the first direction z. The two second side surfaces 44 face away from each other in the third direction y. The two first side surfaces 43 and the two second side surfaces 44 are positioned between the top surface 41 and the base end surface 42 in the first direction z.

As depicted in FIGS. 6 through 9, the semiconductor element 20 is conductively joined to the multiple terminals 10 through flip-chip bonding. The bonding allows the semiconductor element 20 to conduct electrically to the multiple terminals 10. The semiconductor element 20 has a main body 21 and multiple electrodes 22. As indicated in FIG. 1, the semiconductor element 20 is rectangular in shape when viewed in the first direction z.

The main body 21 constitutes the principal part of the semiconductor element 20. The main body 21 includes a semiconductor substrate and semiconductor layers stacked thereon. The semiconductor substrate includes silicon (Si), for example. The semiconductor layers are positioned between the multiple terminals 10 and the semiconductor substrate in the first direction z.

As depicted in FIGS. 6 through 9, the main body 21 includes a first surface 21A and a second surface 21B facing away from each other in the first direction z. Of these surfaces, the second surface 21B faces the multiple terminals 10 in the first direction z. Assumed here, as indicated in FIG. 1, are a first axis X passing through a center C of the first surface 21A and extending in the second direction x and a second axis Y passing through the center C and extending in the third direction y. At this point, the first surface 21A is partitioned into a first region 211, a second region 212, a third region 213, and a fourth region 214. The first region 211 is positioned on one side of the second axis Y in the second direction x. The second region 212 is positioned next to the first region 211 in the third direction y. The third region 213 is positioned next to the second region 212 in the second direction x. The fourth region 214 is positioned next to the third region 213 in the third direction y and next to the first region 211 in the second direction x.

As depicted in FIG. 6 through 9, each of the multiple electrodes 22 conducts to the semiconductor layers of the main body 21 and protrudes from the second surface 21B of the main body 21. The multiple electrodes 22 include copper (Cu), for example. The multiple electrodes 22 are electrically bonded individually to the multiple terminals 10 via a bonding layer 30. The bonding layer 30 may be solder, for example.

As depicted in FIG. 1, the multiple electrodes 22 include a first electrode 221, a second electrode 222, a third electrode 223, a fourth electrode 224, a fifth electrode 225, and a sixth electrode 226. When viewed in the first direction z, the entire first electrode 221 overlaps the first region 211 of the first surface 21A of the main body 21. When viewed in the first direction z, the entire second electrode 222 overlaps the second region 212 of the first surface 21A. When viewed in the first direction z, the entire third electrode 223 overlaps the third region 213 of the first surface 21A. When viewed in the first direction z, the entire fourth electrode 224 overlaps the fourth region 214 of the first surface 21A. When viewed in the first direction z, the entire fifth electrode 225 overlaps the third region 213 of the first surface 21A. When viewed in the first direction z, the entire sixth electrode 226 overlaps the first region 211 of the first surface 21A.

As depicted in FIG. 1, the first electrode 221 is positioned closest to the fourth region 214 of the first surface 21A of the main body 21.

As depicted in FIG. 1, if a first virtual line VL1 passing through the second electrode 222 and extending in the second direction x when viewed in the first direction z is assumed, the first virtual line VL1 overlaps the fifth electrode 225. If a second virtual line VL2 passing through the second electrode 222 and extending in the third direction y when viewed in the first direction z is assumed, the second virtual line VL2 overlaps the sixth electrode 226.

As depicted in FIG. 1, when viewed in the first direction z, positions, shapes, and sizes of the first electrode 221, the second electrode 222, the third electrode 223, the fourth electrode 224, the fifth electrode 225, and the sixth electrode 226 are all substantially the same. The first electrode 221, the second electrode 222, the third electrode 223, the fourth electrode 224, the fifth electrode 225, and the sixth electrode 226 are circular in shape when viewed in the first direction z. Alternatively, these electrodes may be elliptical in shape, for example.

The multiple terminals 10 carry the semiconductor element 20 as depicted in FIGS. 6 through 9. The multiple terminals 10 constitute conductive paths between the semiconductor element 20 and the wiring board on which the semiconductor device A10 is mounted.

As depicted in FIG. 6 through 9, each of the multiple terminals 10 has an element-mounting surface 10A, a board-mounting surface 10B, and an end surface 10C. The element-mounting surface 10A faces the second surface 21B of the main body 21 of the semiconductor element 20 in the first direction z. Each of the multiple electrodes 22 of the semiconductor element 20 is conductively bonded individually to one of the element-mounting surfaces 10A of the multiple terminals 10. The board-mounting surface 10B of the multiple terminals 10 faces a side opposite the element-mounting surface 10A in the first direction z. Each of the board-mounting surfaces 10B of the multiple terminals 10 is exposed from the base end surface 42 of the sealing resin 40. The end surface 10C faces a direction perpendicular to the first direction z, and is positioned between the element-mounting surface 10A and the board-mounting surface 10B in the first direction z. Each of the end surfaces 10C of the multiple terminals 10 is exposed from one of the two first side surfaces 43 and two second side surfaces 44 of the sealing resin 40.

As depicted in FIGS. 1 through 3, the multiple terminals 10 include a first terminal 101, a second terminal 102, a third terminal 103, a fourth terminal 104, a fifth terminal 105, and a sixth terminal 106. As indicated in FIGS. 6 through 9, the first electrode 221 of the semiconductor element 20 is conductively bonded to the element-mounting surface 10A of the first terminal 101. The second electrode 222 of the semiconductor element 20 is conductively bonded to the element-mounting surface 10A of the second terminal 102. The third electrode 223 of the semiconductor element 20 is conductively bonded to the element-mounting surface 10A of the third terminal 103. The fourth electrode 224 of the semiconductor element 20 is conductively bonded to the element-mounting surface 10A of the fourth terminal 104. The fifth electrode 225 of the semiconductor element 20 is conductively bonded to the element-mounting surface 10A of the fifth terminal 105. The sixth electrode 226 of the semiconductor element 20 is conductively bonded to the element-mounting surface 10A of the sixth terminal 106.

As depicted in FIG. 2, the first terminal 101 has a first junction region 11. The first junction region 11 is a portion of the element-mounting surface 10A of the first terminal 101. The first junction region 11 faces the first electrode 221 of the semiconductor element 20. When viewed in the first direction z, a position, a shape, and a size of the first junction region 11 are substantially the same as those of the first electrode 221. The second terminal 102 has a second junction region 12. The second junction region 12 is a portion of the element-mounting surface 10A of the second terminal 102. The second junction region 12 faces the second electrode 222 of the semiconductor element 20. When viewed in the first direction z, a position, a shape, and a size of the second junction region 12 are substantially the same as those of the second electrode 222. The third terminal 103 has a third junction region 13. The third junction region 13 is a portion of the element-mounting surface 10A of the third terminal 103. The third junction region 13 faces the third electrode 223 of the semiconductor element 20. When viewed in the first direction z, a position, a shape, and a size of the third junction region 13 are substantially the same as those of the third electrode 223. The fourth terminal 104 has a fourth junction region 14. The fourth junction region 14 is a portion of the element-mounting surface 10A of the fourth terminal 104. The fourth junction region 14 faces the fourth electrode 224 of the semiconductor element 20. When viewed in the first direction z, a position, a shape, and a size of the fourth junction region 14 are substantially the same as those of the fourth electrode 224.

The first junction region 11, the second junction region 12, the third junction region 13, and the fourth junction region 14 may each be a plating layer stacked on copper. This plating layer includes silver (Ag), nickel (Ni), or some other metal different from copper.

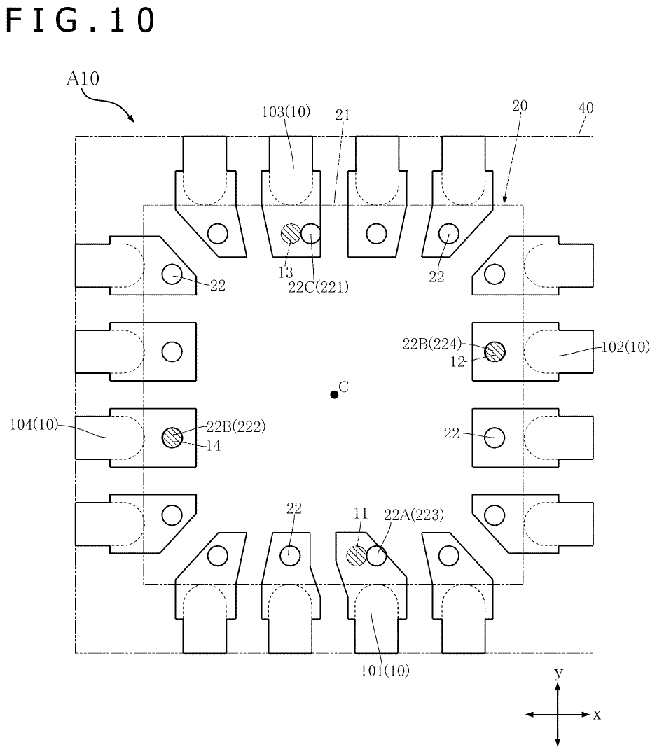

Explained next with reference to FIGS. 10 through 13 is a mounting error of the semiconductor element 20 with respect to the multiple terminals 10. For ease of understanding, the semiconductor element 20 in FIGS. 10 through 13 is seen through the main body 21 thereof and the sealing resin 40.

FIG. 10 depicts a mounting error of the semiconductor element 20 rotated 180 degrees clockwise around an axis extending in the first direction z and passing through the center C.

As depicted in FIG. 10, when viewed in the first direction z, each of the first electrode 221, the second electrode 222, the third electrode 223, and the fourth electrode 224 of the semiconductor element 20 overlaps or comes close to one of the first junction region 11 of the first terminal 101, the second junction region 12 of the second terminal 102, the third junction region 13 of the third terminal 103, and the fourth junction region 14 of the fourth terminal 104. For purpose of explanation here, of the second electrode 222, the third electrode 223, and the fourth electrode 224, the one that overlaps or comes close to the first junction region 11 when viewed in the first direction z is referred to as the first specific electrode 22A. Of the first electrode 221, the second electrode 222, the third electrode 223, and the fourth electrode 224, the one that overlaps or comes close to one of the second junction region 12, the third junction region 13, and the fourth junction region 14 when viewed in the first direction z is referred to as the second specific electrode 22B. Of the first electrode 221, the second electrode 222, the third electrode 223, and the fourth electrode 224, the one which overlaps or comes close to one of the second junction region 12, the third junction region 13, and the fourth junction region 14 when viewed in the first direction z and which is different from the second specific electrode 22B is referred to as the third specific electrode 22C. The first specific electrode 22A, second specific electrode 22B, and third specific electrode 22C will also apply to the following explanations dealing with topics relating to the mounting errors of the semiconductor element 20.

As depicted in FIG. 10, when viewed in the first direction z, an area of that portion of the first junction region 11 which extends outside the first specific electrode 22A is greater than an area of each of those portions of the second junction region 12 and the fourth junction region 14 which extend outside the second specific electrode 22B. When viewed in the first direction z, an area of that portion of the third junction region 13 which extends outside the third specific electrode 22C is greater than the area of each of those portions of the second junction region 12 and the fourth junction region 14 which extend outside the second specific electrode 22B. In this case, the first specific electrode 22A is the third electrode 223. The second specific electrode 22B is either the second electrode 222 or the fourth electrode 224. The third specific electrode 22C is the first electrode 221. When viewed in the first direction z, the first specific electrode 22A is in contact with the first junction region 11. The third specific electrode 22C is in contact with the third junction region 13.

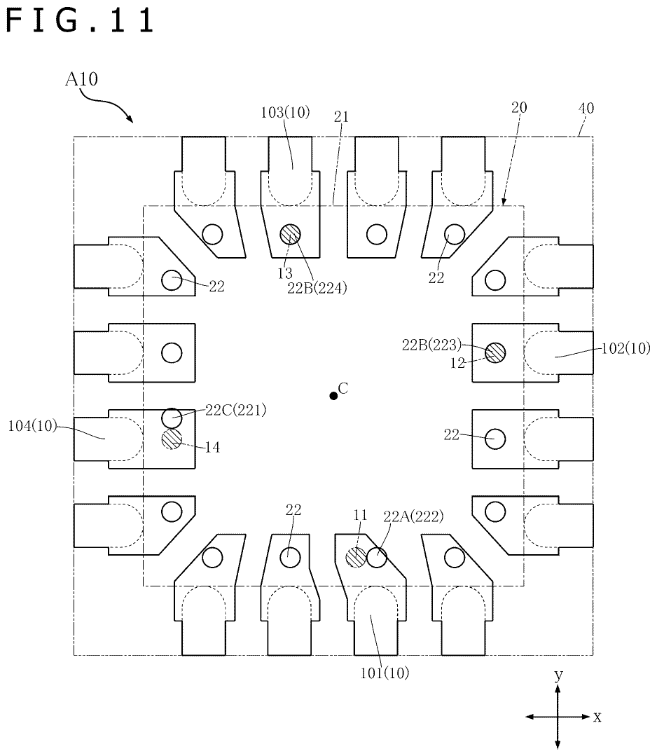

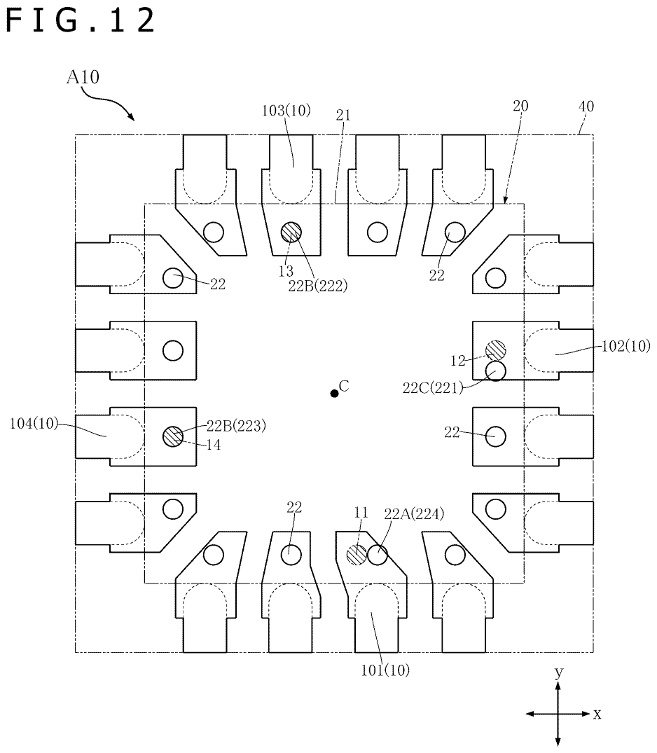

FIG. 11 depicts a mounting error of the semiconductor element 20 rotated 90 degrees clockwise around the axis extending in the first direction z and passing through the center C. Here, the direction “clockwise” refers to the viewpoint from a side facing the first surface 21A of the main body 21 of the semiconductor element 20 in the first direction z, i.e., to the right in planar view.

As depicted in FIG. 11, when viewed in the first direction z, each of the first electrode 221, the second electrode 222, the third electrode 223, and the fourth electrode 224 of the semiconductor element 20 overlaps or comes close to one of the first junction region 11 of the first terminal 101, the second junction region 12 of the second terminal 102, the third junction region 13 of the third terminal 103, and the fourth junction region 14 of the fourth terminal 104.

As depicted in FIG. 11, when viewed in the first direction z, the area of that portion of the first junction region 11 which extends outside the first specific electrode 22A is greater than the area of each of those portions of the second junction region 12 and the fourth junction region 14 which extend outside the second specific electrode 22B. When viewed in the first direction z, the area of that portion of the third junction region 13 which extends outside the third specific electrode 22C is greater than the area of each of those portions of the second junction region 12 and the fourth junction region 14 which extend outside the second specific electrode 22B. In this case, the first specific electrode 22A is the second electrode 222. The second specific electrode 22B is either the third electrode 223 or the fourth electrode 224. The third specific electrode 22C is the first electrode 221. When viewed in the first direction z, the first specific electrode 22A is in contact with the first junction region 11. The third specific electrode 22C is in contact with the fourth junction region 14.

FIG. 12 depicts a mounting error of the semiconductor element 20 rotated 90 degrees counterclockwise around the axis extending in the first direction z and passing through the center C. Here, the direction “counterclockwise” refers to the viewpoint from a side facing the first surface 21A of the main body 21 of the semiconductor element 20 in the first direction z, i.e., to the left in planar view.

As depicted in FIG. 12, when viewed in the first direction z, each of the first electrode 221, the second electrode 222, the third electrode 223, and the fourth electrode 224 of the semiconductor element 20 overlaps or comes close to one of the first junction region 11 of the first terminal 101, the second junction region 12 of the second terminal 102, the third junction region 13 of the third terminal 103, and the fourth junction region of the fourth terminal 104.

As depicted in FIG. 12, when viewed in the first direction z, the area of that portion of the first junction region 11 which extends outside the first specific electrode 22A is greater than the area of each of those portions of the second junction region 12 and the fourth junction region 14 which extend outside the second specific electrode 22B. When viewed in the first direction z, the area of that portion of the third junction region 13 which extends outside the third specific electrode 22C is greater than the area of each of those portions of the second junction region 12 and the fourth junction region 14 which extend outside the second specific electrode 22B. In this case, the first specific electrode 22A is the fourth electrode 224. The second specific electrode 22B is either the second electrode 222 or the third electrode 223. The third specific electrode 22C is the first electrode 221. When viewed in the first direction z, the first specific electrode 22A is in contact with the first junction region 11. The third specific electrode 22C is in contact with the second junction region 12.

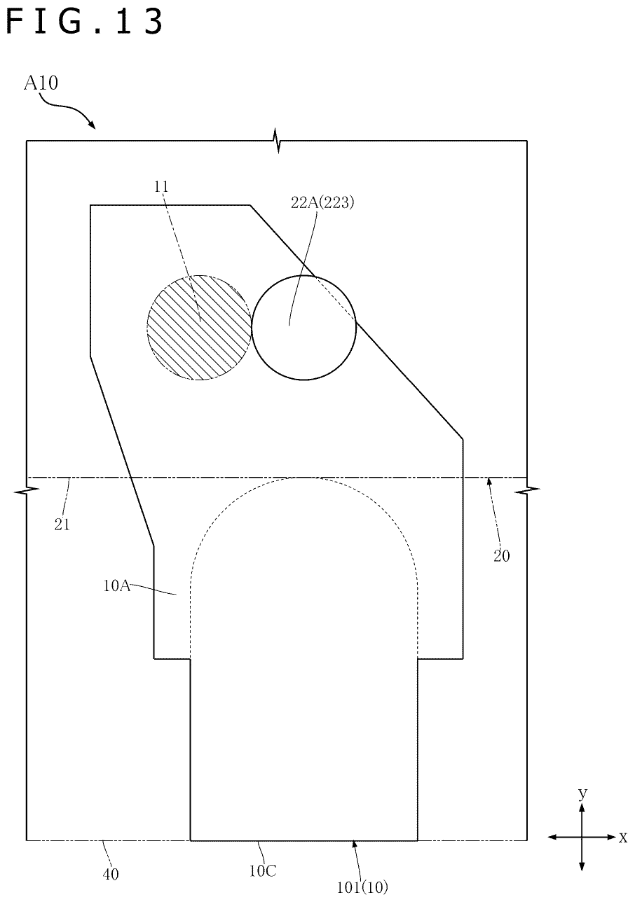

As depicted in FIG. 13, in the case of the mounting error of the semiconductor element 20 in FIG. 10, the first specific electrode 22A is in contact with the first junction region 11 when viewed in the first direction z as discussed above. Further, when viewed in the first direction z, the first specific electrode 22A includes a portion that extends outside the first terminal 101. The relation between the first specific electrode 22A and the first terminal 101 applies not only to the case in FIG. 10 but also to the mounting errors of the semiconductor element 20 in FIGS. 11 and 12.

As described above, in the cases of the mounting errors of the semiconductor element 20 in FIGS. 10 through 13, when viewed in the first direction z, the area of that portion of the first junction region 11 which extends outside the first specific electrode 22A can be said to be greater than the area of each of those portions of the second junction region 12, the third junction region 13, and the fourth junction region 14 which extend outside the second specific electrode 22B. In all, when viewed in the first direction z, the area of one of those portions of the second junction region 12, the third junction region 13, and the fourth junction region 14 which extend outside the third specific electrode 22C can be said to be greater than the area of one of those portions of the second junction region 12, the third junction region 13, and the fourth junction region 14 which extend outside the second specific electrode 22B.

The functions and effects of the semiconductor device A10 are explained next.

The semiconductor device A10 has the first terminal 101, the second terminal 102, the third terminal 103, the fourth terminal 104, and the semiconductor element 20. The semiconductor element 20 has the first electrode 221, the second electrode 222, the third electrode 223, and the fourth electrode 224. Each of the first terminal 101, the second terminal 102, the third terminal 103, and the fourth terminal 104 has the first junction region 11, the second junction region 12, the third junction region 13, and the fourth junction region 14. In the case where the semiconductor element 20 is rotated 90 degrees or 180 degrees around the axis passing through the center C, when viewed in the first direction z, the area of that portion of the first junction region 11 which extends outside the first specific electrode 22A is greater than the area of one of those portions of the second junction region 12, the third junction region 13, and the fourth junction region 14 which extend outside the second specific electrode 22B. With this configuration adopted, upon mounting of the semiconductor element 20 on the multiple terminals 10 during manufacture of the semiconductor device A10, a flux mark transferred from the first specific electrode 22A to the first terminal 101 is confirmed by imaging to deviate more significantly with respect to the first junction region 11 when viewed in the first direction z. This makes it easy to detect the mounting error of the semiconductor element 20 when the semiconductor element 20 is mounted. This configuration thus prevents the mounting error of the semiconductor element 20 on the semiconductor device A10 while improving the manufacturing efficiency of the semiconductor device A10.

When viewed in the first direction z, the first specific electrode 22A includes a portion that extends outside the first terminal 101. With this configuration adopted, when viewed in the first direction z, a shape and a size of the flux mark transferred from the first specific electrode 22A to the first terminal 101 are different from those of the first specific electrode 22A. This makes the difference between the first junction region 11 and the flux mark more explicit. It is thus possible to effectively detect the mounting error of the semiconductor element 20 when the semiconductor element 20 is mounted on the multiple terminals 10.

When viewed in the first direction z, the first specific electrode 22A is in contact with the first junction region 11 of the first terminal 101. This configuration, when adopted, causes the flux mark transferred from the first specific electrode 22A to the first terminal 101 to deviate appreciably with respect to the first junction region 11. It is thus possible to efficiently detect the mounting error of the semiconductor element 20 when the semiconductor element 20 is mounted on the multiple terminals 10.

In the case where the semiconductor element 20 is rotated 90 degrees or 180 degrees around the axis passing through the center C, when viewed in the first direction z, the area of one of those portions of the second junction region 12, the third junction region 13, and the fourth junction region 14 which extend outside the third specific electrode 22C is greater than the area of one of those portions of the second junction region 12, the third junction region 13, and the fourth junction region 14 which extend outside the second specific electrode 22B. This configuration, when adopted, causes the flux mark transferred from the third specific electrode 22C to one of the second terminal 102, the third terminal 103, and the fourth terminal 104 to deviate more significantly with respect to one of the second junction region 12, the third junction region 13, and the fourth junction region 14. Consequently, by directing attention to the third specific electrode 22C in addition to the first specific electrode 22A, it is possible to effectively detect the mounting error of the semiconductor element 20 when the semiconductor element 20 is mounted on the multiple terminals 10.

When viewed in the first direction z, the first electrode 221 of the semiconductor element 20 is positioned closest to the fourth region 214 of the first surface 21A of the semiconductor element 20. This configuration, when adopted, allows each of the first specific electrode 22A, the second specific electrode 22B, and the third specific electrode 22C to establish relations with the first junction region 11, the second junction region 12, the third junction region 13, and the fourth junction region 14.

The semiconductor device A10 further includes the sealing resin 40 that covers the semiconductor element 20. Each of the first terminal 101, the second terminal 102, the third terminal 103, and the fourth terminal 104 has the board-mounting surface 10B and the end surface 10C exposed from the sealing resin 40. The end surface 10C faces a direction perpendicular to the first direction z. With this configuration adopted, when the semiconductor device A10 is mounted on the wiring board, solder is also attached to the end surface 10C. This improves a mounting strength of the semiconductor device A10 with respect to the wiring board.

### Second Embodiment

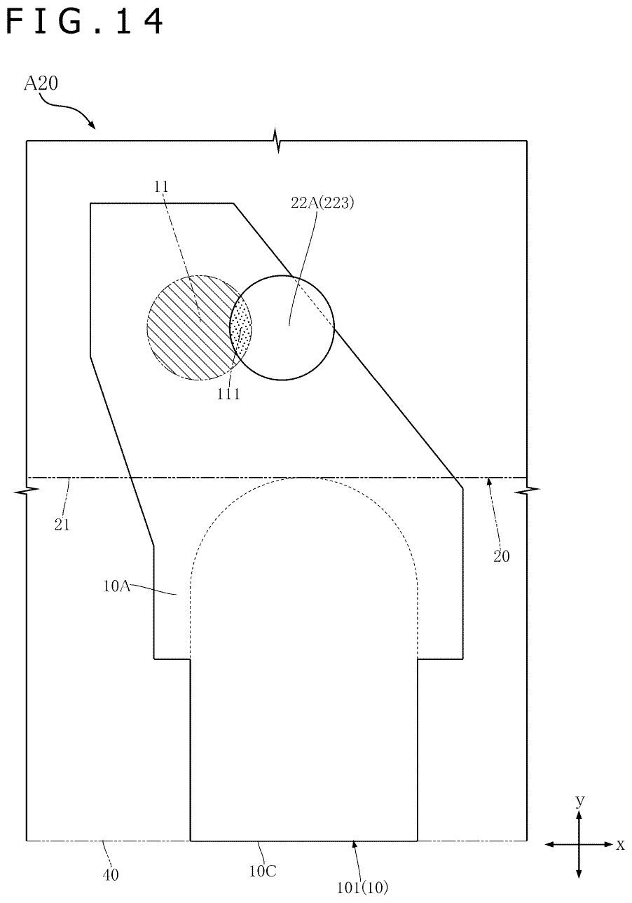

A semiconductor device A20 as a second embodiment of the present disclosure is explained below with reference to FIG. 14. In this and other drawings, the constituent elements identical or similar to those of the above-described semiconductor device A10 are designated by the same reference signs. Duplicate explanations are omitted where appropriate. Here, FIG. 14 corresponds to FIG. 13 depicting the semiconductor device A10.

In the semiconductor device A20, the configuration of the first specific electrode 22A differs from the corresponding one in the semiconductor device A10.

As depicted in FIG. 14, when viewed in the first direction z, the first junction region 11 of the first terminal 101 has an overlap region 111 that overlaps the first specific electrode 22A. The area of the overlap region 111 is 20 percent or less of the total area of the first junction region 11.

The functions and effects of the semiconductor device A20 are explained next.

The semiconductor device A20 has the first terminal 101, the second terminal 102, the third terminal 103, the fourth terminal 104, and the semiconductor element 20. The semiconductor element 20 has the first electrode 221, the second electrode 222, the third electrode 223, and the fourth electrode 224. Each of the first terminal 101, the second terminal 102, the third terminal 103, and the fourth terminal 104 has the first junction region 11, the second junction region 12, the third junction region 13, and the fourth junction region 14. In the case where the semiconductor element 20 is rotated 90 degrees or 180 degrees around the axis passing through the center C, when viewed in the first direction z, the area of that portion of the first junction region 11 which extends outside the first specific electrode 22A is greater than the area of one of those portions of the second junction region 12, the third junction region 13, and the fourth junction region 14 which extend outside the second specific electrode 22B. This configuration thus prevents the mounting error of the semiconductor element 20 also on the semiconductor device A20 while improving the manufacturing efficiency of the semiconductor device A20. Further, the semiconductor device A20 has configurations similar to those of the semiconductor device A10, thereby providing the functions and effects equivalent to those of the semiconductor device A10.

In the semiconductor device A20, when viewed in the first direction z, the first junction region 11 of the first terminal 101 has the overlap region 111 that overlaps the first specific electrode 22A. An area of the overlap region 111 is 20 percent or less of the total area of the first junction region 11. With this configuration adopted, the flux mark transferred from the first specific electrode 22A to the first terminal 101 can be confirmed by imaging to deviate significantly with respect to the first junction region 11 in the case where the first specific electrode 22A overlaps the first junction region 11 when viewed in the first direction z.

### Third Embodiment

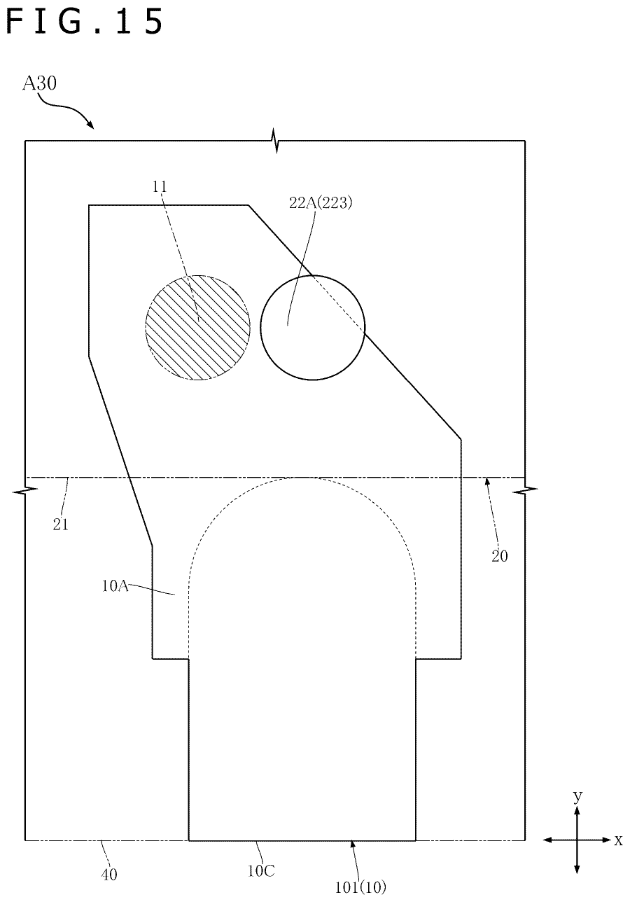

A semiconductor device A30 as a third embodiment of the present disclosure is explained below with reference to FIG. 15. In this and other drawings, the constituent elements identical or similar to those of the above-described semiconductor device A10 are designated by the same reference signs. Duplicate explanations are omitted where appropriate. Here, FIG. 15 corresponds to FIG. 13 depicting the semiconductor device A10.

In the semiconductor device A30, the configuration of the first specific electrode 22A differs from the corresponding one in the semiconductor device A10.

As depicted in FIG. 15, when viewed in the first direction z, the first specific electrode 22A is apart from the first junction region 11 of the first terminal 101.

The functions and effects of the semiconductor device A30 are explained next.

The semiconductor device A30 has the first terminal 101, the second terminal 102, the third terminal 103, the fourth terminal 104, and the semiconductor element 20. The semiconductor element 20 has the first electrode 221, the second electrode 222, the third electrode 223, and the fourth electrode 224. Each of the first terminal 101, the second terminal 102, the third terminal 103, and the fourth terminal 104 has the first junction region 11, the second junction region 12, the third junction region 13, and the fourth junction region 14. In the case where the semiconductor element 20 is rotated 90 degrees or 180 degrees around the axis passing through the center C, when viewed in the first direction z, the area of that portion of the first junction region 11 which extends outside the first specific electrode 22A is greater than the area of one of those portions of the second junction region 12, the third junction region 13, and the fourth junction region 14 which extend outside the second specific electrode 22B. This configuration thus prevents the mounting error of the semiconductor element 20 also on the semiconductor device A30 while improving the manufacturing efficiency of the semiconductor device A30. Further, the semiconductor device A30 has configurations similar to those of the semiconductor device A10, thereby providing the functions and effects equivalent to those of the semiconductor device A10.

In the semiconductor device A30, when viewed in the first direction z, the first specific electrode 22A is apart from the first junction region 11 of the first terminal 101. With this configuration adopted, the entire flux mark transferred from the first specific electrode 22A to the first terminal 101 is located outside the first junction region 11. This makes it possible to detect more efficiently the mounting error of the semiconductor element 20 when the semiconductor element 20 is mounted on the multiple terminals 10.

### Fourth Embodiment

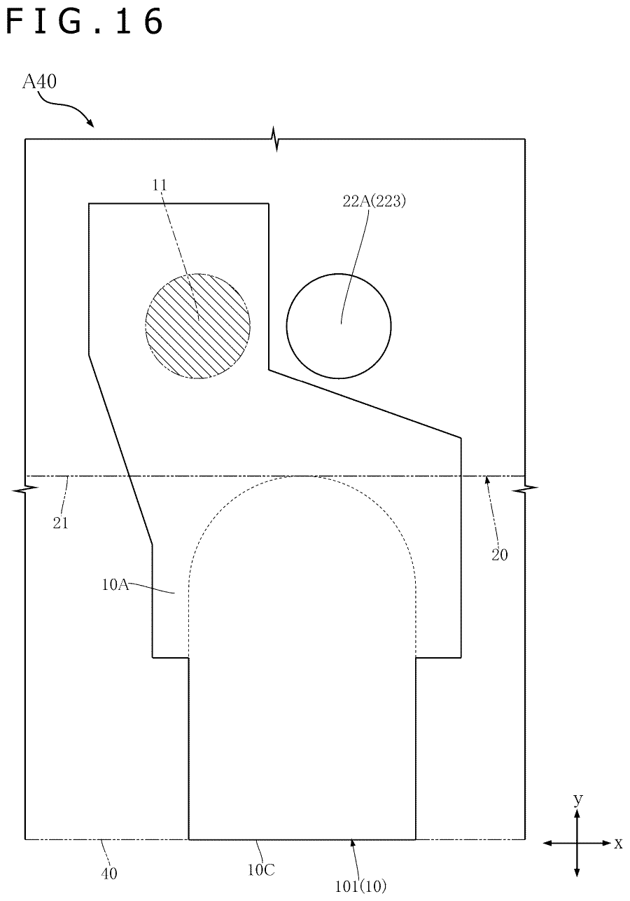

A semiconductor device A40 as a fourth embodiment of the present disclosure is explained below with reference to FIG. 16. In this and other drawings, the constituent elements identical or similar to those of the above-described semiconductor device A10 are designated by the same reference signs. Duplicate explanations are omitted where appropriate. Here, FIG. 16 corresponds to FIG. 13 depicting the semiconductor device A10.

In the semiconductor device A40, the configuration of the first specific electrode 22A differs from the corresponding one in the semiconductor device A10.

As depicted in FIG. 16, when viewed in the first direction z, the first specific electrode 22A is apart from the first terminal 101.

The functions and effects of the semiconductor device A40 are explained next.

The semiconductor device A40 has the first terminal 101, the second terminal 102, the third terminal 103, the fourth terminal 104, and the semiconductor element 20. The semiconductor element 20 has the first electrode 221, the second electrode 222, the third electrode 223, and the fourth electrode 224. Each of the first terminal 101, the second terminal 102, the third terminal 103, and the fourth terminal 104 has the first junction region 11, the second junction region 12, the third junction region 13, and the fourth junction region 14. In the case where the semiconductor element 20 is rotated 90 degrees or 180 degrees around the axis passing through the center C, when viewed in the first direction z, the area of that portion of the first junction region 11 which extends outside the first specific electrode 22A is greater than the area of one of those portions of the second junction region 12, the third junction region 13, and the fourth junction region 14 which extend outside the second specific electrode 22B. This configuration thus prevents the mounting error of the semiconductor element 20 also on the semiconductor device A40 while improving the manufacturing efficiency of the semiconductor device A40. Further, the semiconductor device A40 has configurations similar to those of the semiconductor device A10, thereby providing the functions and effects equivalent to those of the semiconductor device A10.

In the semiconductor device A40, when viewed in the first direction z, the first specific electrode 22A is apart from the first junction region 11 of the first terminal 101. With this configuration adopted, the flux mark is not transferred from the first specific electrode 22A to the first terminal 101. This makes it possible to detect more efficiently the mounting error of the semiconductor element 20 when the semiconductor element 20 is mounted on the multiple terminals 10.

### Fifth Embodiment

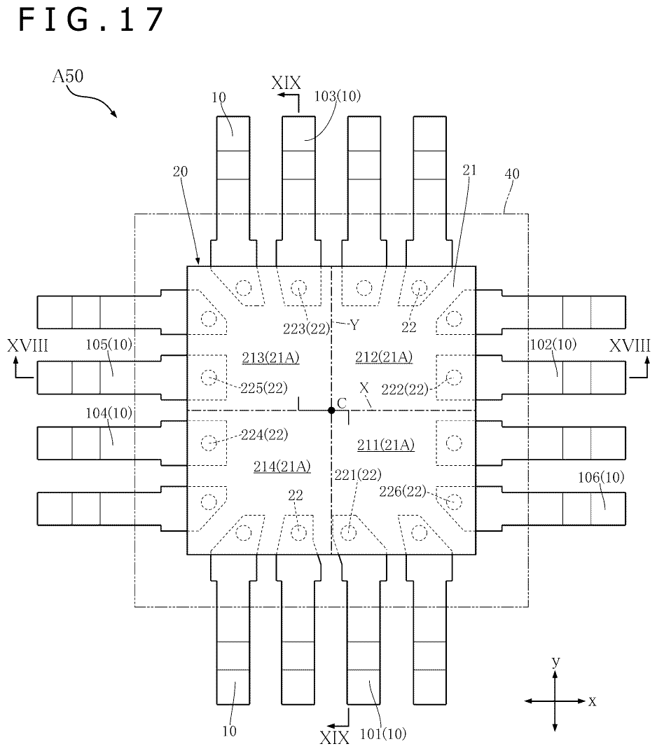

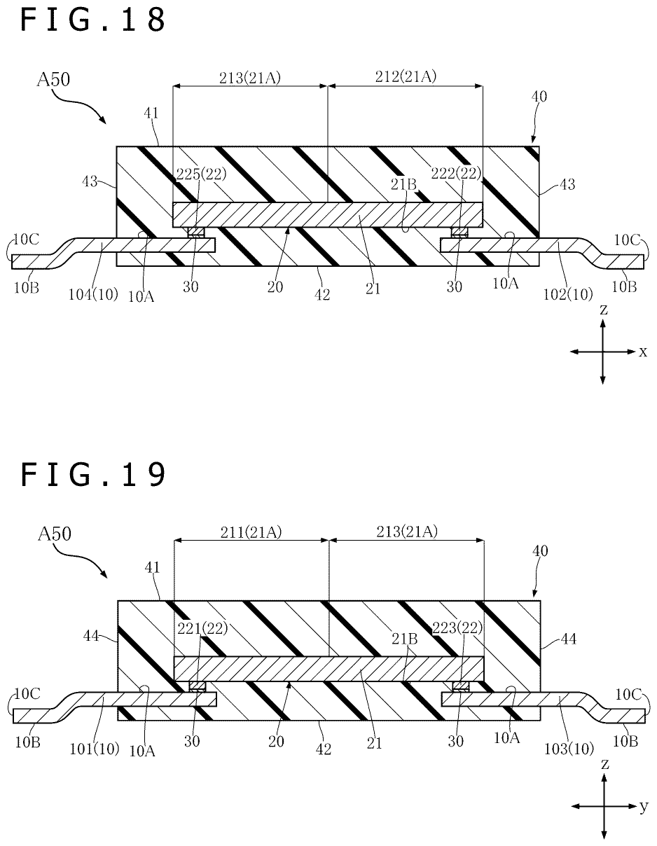

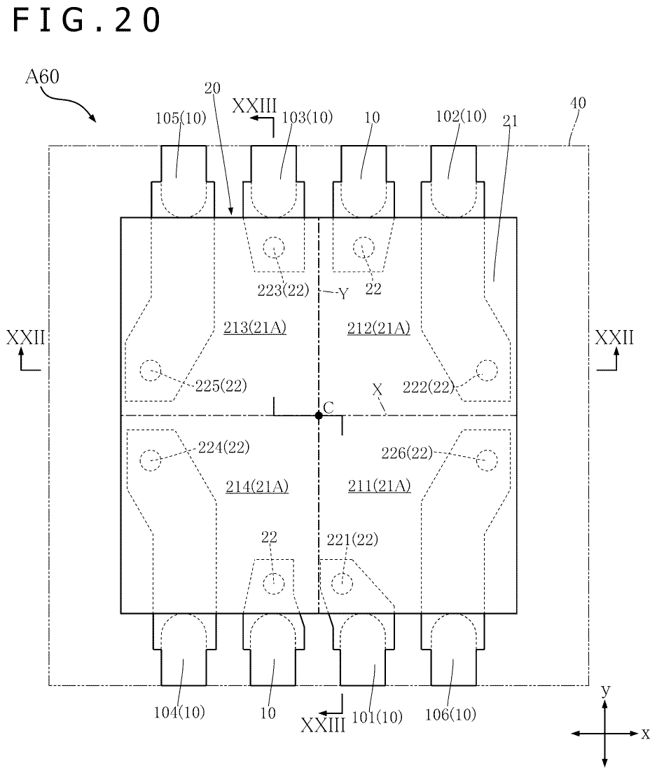

A semiconductor device A50 as a fifth embodiment of the present disclosure is explained below with reference to FIGS. 17 through 19. In these and other drawings, the constituent elements identical or similar to those of the above-described semiconductor device A10 are designated by the same reference signs. Duplicate explanations are omitted where appropriate. Here, FIG. 17 depicts the semiconductor device A50 seen through the sealing resin 40 for ease of understanding. In FIG. 17, the transparent sealing resin 40 is indicated by imaginary lines.

In the semiconductor device A50, the configuration of the multiple terminals 10 differs from the corresponding one in the semiconductor device A10. The package format of the semiconductor device A50 is a quad flat package (QFP).

As depicted in FIGS. 17 through 19, each of the multiple terminals 10 protrudes from one of the two first side surfaces 43 and two second side surfaces 44 of the sealing resin 40. When viewed in the second direction x or in the third direction y, each of the multiple terminals 10 protruding from one of the two first side surfaces 43 and the two second side surfaces 44 is bent in gull-wing fashion. The bent terminals each include the board-mounting surface 10B and the end surface 10C. Thus, when viewed in the first direction z, the board-mounting surface 10B and the end surface 10C of each of the multiple terminals 10 are apart from the sealing resin 40.

The functions and effects of the semiconductor device A50 are explained next.

The semiconductor device A50 has the first terminal 101, the second terminal 102, the third terminal 103, the fourth terminal 104, and the semiconductor element 20. The semiconductor element 20 has the first electrode 221, the second electrode 222, the third electrode 223, and the fourth electrode 224. Each of the first terminal 101, the second terminal 102, the third terminal 103, and the fourth terminal 104 has the first junction region 11, the second junction region 12, the third junction region 13, and the fourth junction region 14. In the case where the semiconductor element 20 is rotated 90 degrees or 180 degrees around the axis passing through the center C, when viewed in the first direction z, the area of that portion of the first junction region 11 which extends outside the first specific electrode 22A is greater than the area of one of those portions of the second junction region 12, the third junction region 13, and the fourth junction region 14 which extend outside the second specific electrode 22B. This configuration thus prevents the mounting error of the semiconductor element 20 also on the semiconductor device A50 while improving the manufacturing efficiency of the semiconductor device A50. Further, the semiconductor device A50 has configurations similar to those of the semiconductor device A10, thereby providing the functions and effects equivalent to those of the semiconductor device A10.

### Sixth Embodiment

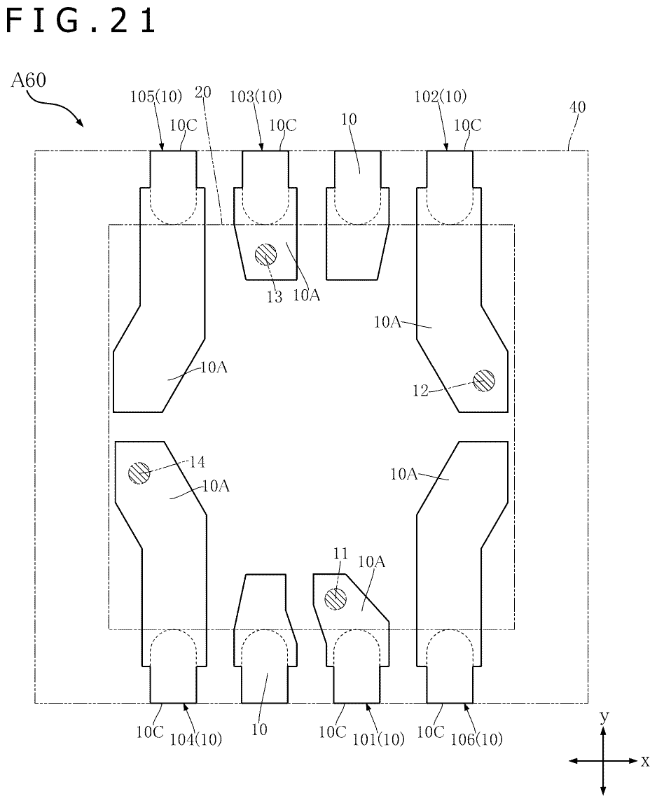

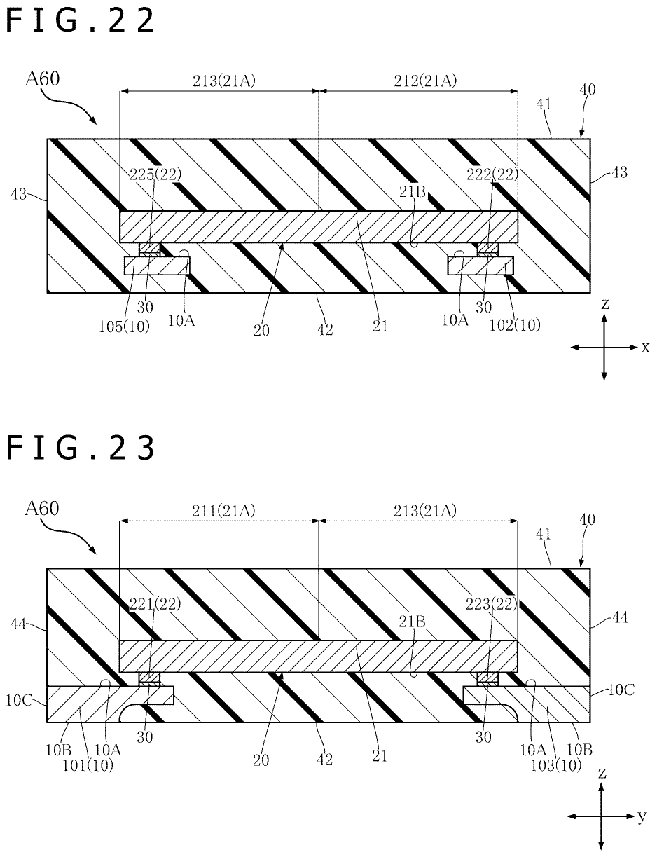

A semiconductor device A60 as a sixth embodiment of the present disclosure is explained below with reference to FIGS. 20 through 23. In these and other drawings, the constituent elements identical or similar to those of the above-described semiconductor device A10 are designated by the same reference signs. Duplicate explanations are omitted where appropriate. Here, FIG. 20 depicts the semiconductor device A60 seen through the sealing resin 40 for ease of understanding. In FIG. 20, the transparent sealing resin 40 is indicated by imaginary lines.

In the semiconductor device A60, the configuration of the multiple terminals 10 differs from the corresponding one in the semiconductor device A10. The package format of the semiconductor device A60 is a small outline non-leaded package (SON).

As depicted in FIGS. 20 through 23, the end surface 10C of each of the multiple terminals 10 is exposed from one of the two first side surfaces 43 of the sealing resin 40. The multiple terminals 10 are each apart from the two second side surfaces 44 of the sealing resin 40.

As depicted in FIG. 20, when viewed in the first direction z, two terminals 10 overlap each of the first region 211, the second region 212, the third region 213, and the fourth region 214 of the first surface 21A of the semiconductor element 20. Two electrodes 22 of the semiconductor element 20 that are conductively bonded to the two overlapping terminals 10 include an electrode 22 positioned closest to the first axis X when viewed in the first direction z and an electrode 22 positioned closest to the second axis Y when viewed in the first direction z. The position of each of the two electrodes 22, when viewed in the first direction z, overlaps the position of one of the multiple electrodes 22 mounted on the semiconductor device A60.

The functions and effects of the semiconductor device A60 are explained next.

The semiconductor device A60 has the first terminal 101, the second terminal 102, the third terminal 103, the fourth terminal 104, and the semiconductor element 20. The semiconductor element 20 has the first electrode 221, the second electrode 222, the third electrode 223, and the fourth electrode 224. Each of the first terminal 101, the second terminal 102, the third terminal 103, and the fourth terminal 104 has the first junction region 11, the second junction region 12, the third junction region 13, and the fourth junction region 14. In the case where the semiconductor element 20 is rotated 90 degrees or 180 degrees around the axis passing through the center C, when viewed in the first direction z, the area of that portion of the first junction region 11 which extends outside the first specific electrode 22A is greater than the area of one of those portions of the second junction region 12, the third junction region 13, and the fourth junction region 14 which extend outside the second specific electrode 22B. This configuration thus prevents the mounting error of the semiconductor element 20 also on the semiconductor device A60 while improving the manufacturing efficiency of the semiconductor device A60. Further, the semiconductor device A60 has configurations similar to those of the semiconductor device A10, thereby providing the functions and effects equivalent to those of the semiconductor device A10.

### Seventh Embodiment

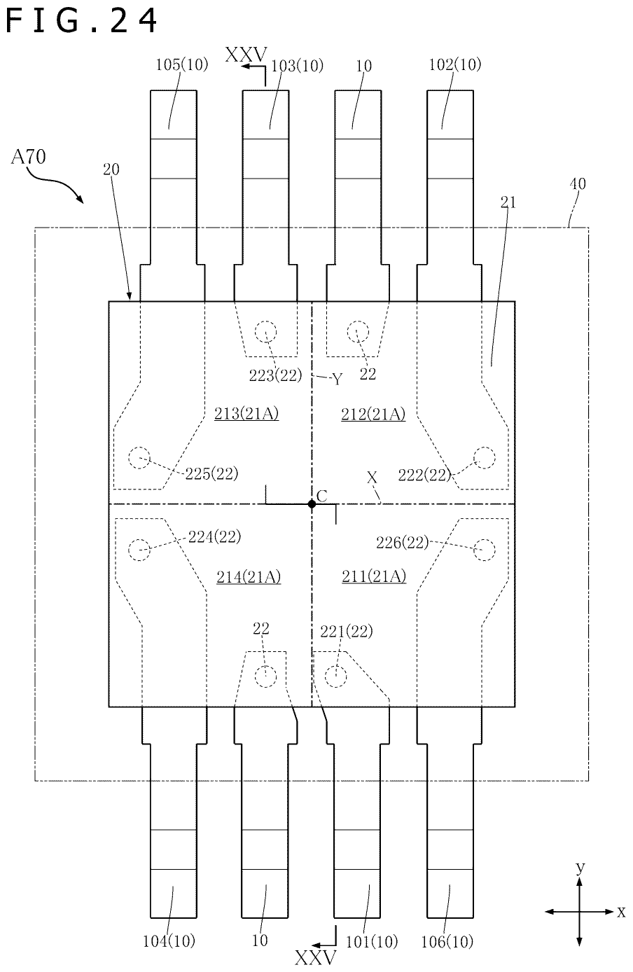

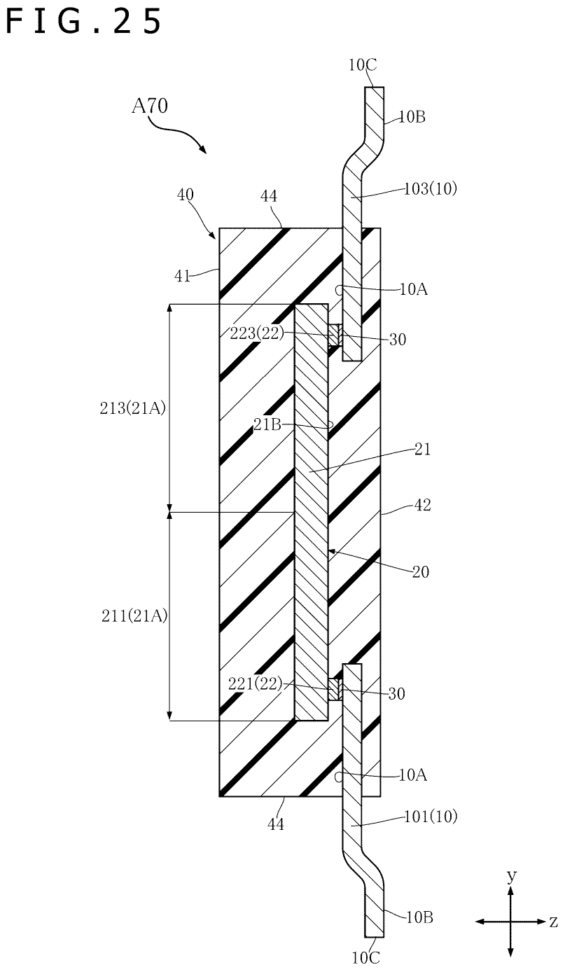

A semiconductor device A70 as a seventh embodiment of the present disclosure is explained below with reference to FIGS. 24 and 25. In these and other drawings, the constituent elements identical or similar to those of the above-described semiconductor device A10 are designated by the same reference signs. Duplicate explanations are omitted where appropriate. Here, FIG. 24 depicts the semiconductor device A70 seen through the sealing resin 40 for ease of understanding. In FIG. 24, the transparent sealing resin 40 is indicated by imaginary lines.

In the semiconductor device A70, the configuration of the multiple terminals 10 differs from the corresponding one in the semiconductor device A60. The package format of the semiconductor device A70 is a small outline package (SOP).

As depicted in FIGS. 24 and 25, each of the multiple terminals 10 protrudes from one of the two first side surfaces 43 of the sealing resin 40. When viewed in the second direction x, each of the multiple terminals 10 protruding from one of the two first side surfaces 43 is bent in gull-wing fashion. The bent terminals each include the board-mounting surface 10B and the end surface 10C. Thus, when viewed in the first direction z, the board-mounting surface 10B and the end surface 10C of each of the multiple terminals 10 are apart from the sealing resin 40.

The functions and effects of the semiconductor device A70 are explained next.

The semiconductor device A70 has the first terminal 101, the second terminal 102, the third terminal 103, the fourth terminal 104, and the semiconductor element 20. The semiconductor element 20 has the first electrode 221, the second electrode 222, the third electrode 223, and the fourth electrode 224. Each of the first terminal 101, the second terminal 102, the third terminal 103, and the fourth terminal 104 has the first junction region 11, the second junction region 12, the third junction region 13, and the fourth junction region 14. In the case where the semiconductor element 20 is rotated 90 degrees or 180 degrees around the axis passing through the center C, when viewed in the first direction z, the area of that portion of the first junction region 11 which extends outside the first specific electrode 22A is greater than the area of one of those portions of the second junction region 12, the third junction region 13, and the fourth junction region 14 which extend outside the second specific electrode 22B. This configuration thus prevents the mounting error of the semiconductor element 20 also on the semiconductor device A70 while improving the manufacturing efficiency of the semiconductor device A70. Further, the semiconductor device A70 has configurations similar to those of the semiconductor device A10, thereby providing the functions and effects equivalent to those of the semiconductor device A10.

The embodiments discussed above are not limitative of the present disclosure. The specific configurations of each of the parts described in this disclosure may be diversely varied in design as desired.

The present disclosure includes the embodiments stated in the following additional notes:

### [Additional Note 1]

A semiconductor device (A10) including:
a semiconductor element (20) having a main body (21) that includes a first surface (21A) and a second surface (21B) facing away from each other in a first direction; and
a first terminal (101), a second terminal (102), a third terminal (103), and a fourth terminal (104) each facing the second surface (21B),
in which the semiconductor element (20) has a first electrode (221), a second electrode (222), a third electrode (223), and a fourth electrode (224) positioned closer to the second surface (21B) than the first surface (21A),
the first electrode (221), the second electrode (222), the third electrode (223), and the fourth electrode (224) are conductively bonded to the first terminal (101), the second terminal (102), the third terminal (103), and the fourth terminal (104), respectively,
when a first axis (X) passing through a center (C) of the first surface (21A) and extending in a second direction (x) perpendicular to the first direction (z) and a second axis (Y) passing through the center (C) and extending in a third direction (y) perpendicular to the first direction (z) and to the second direction (x) are assumed on the first surface (21A),
the first surface (21A) is partitioned into a first region (211) positioned on one side of the second axis (Y) in the second direction (x), a second region (212) positioned next to the first region (211) in the third direction (y), a third region (213) positioned next to the second region (212) in the second direction (x), and a fourth region (214) positioned next to the third region (213) in the third direction (y) and next to the first region (211) in the second direction (x),
the first electrode (221), the second electrode (222), the third electrode (223), and the fourth electrode (224) overlap the first region (211), the second region (212), the third region (213), and the fourth region (214), respectively, when viewed in the first direction (z),
the first terminal (101) has a first junction region (11) that faces the first electrode (221) and has a position, a shape, and a size substantially the same as those of the first electrode (221) when viewed in the first direction (z),
the second terminal (102) has a second junction region (12) that faces the second electrode (222) and has a position, a shape, and a size substantially the same as those of the second electrode (222) when viewed in the first direction (z),
the third terminal (103) has a third junction region (13) that faces the third electrode (223) and has a position, a shape, and a size substantially the same as those of the third electrode (223) when viewed in the first direction (z),
the fourth terminal (104) has a fourth junction region (14) that faces the fourth electrode (224) and has a position, a shape, and a size substantially the same as those of the fourth electrode (224) when viewed in the first direction (z),
in a case where the semiconductor element (20) is rotated 90 degrees or 180 degrees around an axial center extending in the first direction (z) and passing through the center (C),
each of the first electrode (221), the second electrode (222), the third electrode (223), and the fourth electrode (224) overlaps or comes close to one of the first junction region (11), the second junction region (12), the third junction region (13), and the fourth junction region (14) when viewed in the first direction (z), and
when it is assumed that, of the second electrode (222), the third electrode (223), and the fourth electrode (224), the one that overlaps or comes close to the first junction region (11) when viewed in the first direction (z) is a first specific electrode (22A),
and that, of the first electrode (221), the second electrode (222), the third electrode (223), and the fourth electrode (224), the one that overlaps or comes close to one of the second junction region (12), the third junction region (13), and the fourth junction region (14) when viewed in the first direction (z) is a second specific electrode (22B),
an area of that portion of the first junction region (11) that extends outside the first specific electrode (22A) is greater than an area of one of those portions of the second junction region (12), the third junction region (13), and the fourth junction region (14) that extend outside the second specific electrode (22B), when viewed in the first direction (z).

### [Additional Note 2]

The semiconductor device (A10) as stated in the additional note 1,
in which the first specific electrode (22A) has a portion that extends outside the first terminal (101) when viewed in the first direction (z).

### [Additional Note 3]

The semiconductor device (A10) as stated in the additional note 2,
in which the first specific electrode (22A) is joined to the first junction region (11) when viewed in the first direction (z).

### [Additional Note 4]

The semiconductor device (A10) as stated in the additional note 3,
in which the first specific electrode (22A) is in contact with the first junction region (11) when viewed in the first direction (z).

### [Additional Note 5]

The semiconductor device (A20) as stated in the additional note 3,
in which the first junction region (11) has an overlap region (111) that overlaps the first specific electrode (22A) when viewed in the first direction (z), and
an area of the overlap region (111) is 20 percent or less of the entire area of the first junction region (11).

### [Additional Note 6]

The semiconductor device (A30) as stated in the additional note 2,
in which the first specific electrode (22A) is apart from the first junction region (11) when viewed in the first direction (z).

### [Additional Note 7]

The semiconductor device (A40) as stated in the additional note 6,
in which the first specific electrode (22A) is apart from the first terminal (101) when viewed in the first direction (z).

### [Additional Note 8]

The semiconductor device (A10) as stated in the additional note 2,
in which the first electrode (221) comes closest to the fourth region (214) when viewed in the first direction (z).

### [Additional Note 9]

The semiconductor device (A10) as stated in the additional note 8, further including: a fifth terminal (105),
in which the semiconductor element (20) has a fifth electrode (225) that is positioned closer to the second surface (21B) than the first surface (21A) and overlaps the third region (213) when viewed in the first direction (z),
the fifth electrode (225) is conductively bonded to the fifth terminal (105), and
when a first virtual line (VL1) passing through the second electrode (222) when viewed in the first direction (z) and extending in the second direction (x) is assumed,
the first virtual line (VL1) overlaps the fifth electrode (225) when viewed in the first direction (z).

### [Additional Note 10]

The semiconductor device (A10) as stated in the additional note 9, further including:
a sixth terminal (106),
in which the semiconductor element (20) has a sixth electrode (226) that is positioned closer to the second surface (21B) than the first surface (21A) and overlaps the first region (211) when viewed in the first direction (z),
the sixth electrode (226) is conductively bonded to the sixth terminal (106), and
when a second virtual line (VL2) passing through the second electrode (222) when viewed in the first direction (z) and extending in the third direction (y) is assumed,
the second virtual line (VL2) overlaps the sixth electrode (226) when viewed in the first direction (z).

### [Additional Note 11]

The semiconductor device as stated in the additional note 10,
in which, in a case where the semiconductor element (20) is rotated 90 degrees or 180 degrees around the axial center,
and when, of the first electrode (221), the second electrode (222), the third electrode (223), and the fourth electrode (224), the one that overlaps or comes close to one of the second junction region (12), the third junction region (13), and the fourth junction region (14) when viewed in the first direction (z) and is different from the second specific electrode (22B) is assumed to be a third specific electrode (22C),
an area of one of those portions of the second junction region (12), the third junction region (13), and the fourth junction region (14) that are positioned outside the third specific electrode (22C) when viewed in the first direction (z) is greater than an area of one of those portions of the second junction region (12), the third junction region (13), and the fourth junction region (14) that are positioned outside the second specific electrode (22B).

### [Additional Note 12]

The semiconductor device (A10) as stated in the additional note 11,
in which the third specific electrode (22C) is the first electrode (221).

### [Additional Note 13]

The semiconductor device (A10) as stated in the additional note 12,
in which the third specific electrode (22C) is in contact with one of the second junction region (12), the third junction region (13), and the fourth junction region (14) when viewed in the first direction (z).

### [Additional Note 14]

The semiconductor device (A10) as stated in one of the additional notes 2 through 13,
in which each of the first electrode (221), the second electrode (222), the third electrode (223), and the fourth electrode (224) protrudes from the second surface (21B).

### [Additional Note 15]

The semiconductor device (A10) as stated in the additional note 14,
in which the first electrode (221), the second electrode (222), the third electrode (223), and the fourth electrode (224) are substantially same in shape and size when viewed in the first direction (z).

### [Additional Note 16]

The semiconductor device (A10) as stated in the additional note 14, further including:
a sealing resin (40) that covers the semiconductor element (20),
in which each of the first terminal (101), the second terminal (102), the third terminal (103), and the fourth terminal (104) has a board-mounting surface (10B) that faces a same side as the second surface (21B) when viewed in the first direction (z), and
the board-mounting surface (10B) of each of the first terminal (101), the second terminal (102), the third terminal (103), and the fourth terminal (104) is exposed from the sealing resin (40).

### [Additional Note 17]

The semiconductor device as stated in the additional note 16,
in which each of the first terminal (101), the second terminal (102), the third terminal (103), and the fourth terminal (104) has an end surface (10C) that faces a direction perpendicular to the first direction (z), and
the end surface (10C) of each of the first terminal (101), the second terminal (102), the third terminal (103), and the fourth terminal (104) is exposed from the sealing resin (40).

### [Additional Note 18]

The semiconductor device as stated in the additional note 17,
in which the sealing resin (40) has multiple side surfaces (43, 44) facing a direction perpendicular to the first direction (z), and
each of the first terminal (101), the second terminal (102), the third terminal (103), and the fourth terminal (104) protrudes from one of the multiple side surfaces (43, 44).

The present disclosure contains subject matter related to that disclosed in Japanese Priority Patent Application JP 2025-035538 filed in the Japan Patent Office on Mar. 6, 2025, the entire content of which is hereby incorporated by reference.

What is claimed is:

1. A semiconductor device comprising:
a semiconductor element having a main body that includes a first surface and a second surface facing away from each other in a first direction; and
a first terminal, a second terminal, a third terminal, and a fourth terminal each facing the second surface,
wherein the semiconductor element has a first electrode, a second electrode, a third electrode, and a fourth electrode positioned closer to the second surface than the first surface,
the first electrode, the second electrode, the third electrode, and the fourth electrode are conductively bonded to the first terminal, the second terminal, the third terminal, and the fourth terminal, respectively,
when a first axis passing through a center of the first surface and extending in a second direction perpendicular to the first direction and a second axis passing through the center and extending in a third direction perpendicular to the first direction and to the second direction are assumed on the first surface,
the first surface is partitioned into a first region positioned on one side of the second axis in the second direction, a second region positioned next to the first region in the third direction, a third region positioned next to the second region in the second direction, and a fourth region positioned next to the third region in the third direction and next to the first region in the second direction,
the first electrode, the second electrode, the third electrode, and the fourth electrode overlap the first region, the second region, the third region, and the fourth region, respectively, when viewed in the first direction,
the first terminal has a first junction region that faces the first electrode and has a position, a shape, and a size substantially same as those of the first electrode when viewed in the first direction,
the second terminal has a second junction region that faces the second electrode and has a position, a shape, and a size substantially same as those of the second electrode when viewed in the first direction,
the third terminal has a third junction region that faces the third electrode and has a position, a shape, and a size substantially same as those of the third electrode when viewed in the first direction,
the fourth terminal has a fourth junction region that faces the fourth electrode and has a position, a shape, and a size substantially same as those of the fourth electrode when viewed in the first direction,
in a case where the semiconductor element is rotated 90 degrees or 180 degrees around an axial center extending in the first direction and passing through the center,
each of the first electrode, the second electrode, the third electrode, and the fourth electrode overlaps or comes close to one of the first junction region, the second junction region, the third junction region, and the fourth junction region when viewed in the first direction, and
when it is assumed that, of the second electrode, the third electrode, and the fourth electrode, the one that overlaps or comes close to the first junction region when viewed in the first direction is a first specific electrode,
and that, of the first electrode, the second electrode, the third electrode, and the fourth electrode, the one that overlaps or comes close to one of the second junction region, the third junction region, and the fourth junction region when viewed in the first direction is a second specific electrode,
an area of that portion of the first junction region that extends outside the first specific electrode is greater than an area of one of those portions of the second junction region, the third junction region, and the fourth junction region that extend outside the second specific electrode, when viewed in the first direction.

2. The semiconductor device according to claim 1,
wherein the first specific electrode has a portion that extends outside the first terminal when viewed in the first direction.

3. The semiconductor device according to claim 2,
wherein the first specific electrode is joined to the first junction region when viewed in the first direction.

4. The semiconductor device according to claim 3,
wherein the first specific electrode is in contact with the first junction region when viewed in the first direction.

5. The semiconductor device according to claim 3,
wherein the first junction region has an overlap region that overlaps the first specific electrode when viewed in the first direction, and
an area of the overlap region is 20 percent or less of the entire area of the first junction region.

6. The semiconductor device according to claim 2,
wherein the first specific electrode is apart from the first junction region when viewed in the first direction.

7. The semiconductor device according to claim 6,
wherein the first specific electrode is apart from the first terminal when viewed in the first direction.

8. The semiconductor device according to claim 2,
wherein the first electrode comes closest to the fourth region when viewed in the first direction.

9. The semiconductor device according to claim 8, further comprising:
a fifth terminal,
wherein the semiconductor element has a fifth electrode that is positioned closer to the second surface than the first surface and overlaps the third region when viewed in the first direction,
the fifth electrode is conductively bonded to the fifth terminal, and
when a first virtual line passing through the second electrode when viewed in the first direction and extending in the second direction is assumed,
the first virtual line overlaps the fifth electrode when viewed in the first direction.

10. The semiconductor device according to claim 9, further comprising:
a sixth terminal,
wherein the semiconductor element has a sixth electrode that is positioned closer to the second surface than the first surface and overlaps the first region when viewed in the first direction,
the sixth electrode is conductively bonded to the sixth terminal, and
when a second virtual line passing through the second electrode when viewed in the first direction and extending in the third direction is assumed,
the second virtual line overlaps the sixth electrode when viewed in the first direction.

11. The semiconductor device according to claim 10,
wherein, in a case where the semiconductor element is rotated 90 degrees or 180 degrees around the axial center,
and when, of the first electrode, the second electrode, the third electrode, and the fourth electrode, the one that overlaps or comes close to one of the second junction region, the third junction region, and the fourth junction region when viewed in the first direction and is different from the second specific electrode is assumed to be a third specific electrode,
an area of one of those portions of the second junction region, the third junction region, and the fourth junction region that are positioned outside the third specific electrode when viewed in the first direction is greater than an area of one of those portions of the second junction region, the third junction region, and the fourth junction region that are positioned outside the second specific electrode.

12. The semiconductor device according to claim 11,
wherein the third specific electrode is the first electrode.

13. The semiconductor device according to claim 12,
wherein the third specific electrode is in contact with one of the second junction region, the third junction region, and the fourth junction region when viewed in the first direction.

14. The semiconductor device according to claim 2,
wherein each of the first electrode, the second electrode, the third electrode, and the fourth electrode protrudes from the second surface.

15. The semiconductor device according to claim 14,
wherein the first electrode, the second electrode, the third electrode, and the fourth electrode are substantially same in shape and size when viewed in the first direction.

16. The semiconductor device according to claim 14, further comprising:
a sealing resin that covers the semiconductor element,
wherein each of the first terminal, the second terminal, the third terminal, and the fourth terminal has a board-mounting surface that faces a same side as the second surface when viewed in the first direction, and
the board-mounting surface of each of the first terminal, the second terminal, the third terminal, and the fourth terminal is exposed from the sealing resin.

17. The semiconductor device according to claim 16,
wherein each of the first terminal, the second terminal, the third terminal, and the fourth terminal has an end surface that faces a direction perpendicular to the first direction, and
the end surface of each of the first terminal, the second terminal, the third terminal, and the fourth terminal is exposed from the sealing resin.
